(19) United States
(12) Patent Application Publication
(10) Pub. No.: US 2017/0163236 A1
(43) Pub. Date: Jun. 8, 2017

(54) HIGH POWER PHASE SHIFTER

(71) Applicant: Alcatel Lucent, Boulogne-Billancourt (FR)

(72) Inventors: Michel Rixain, Guyancourt (FR); Jean-Luc Galiez, Emance (FR)

(21) Appl. No.: 15/437,801

(22) Filed: Feb. 21, 2017

Related U.S. Application Data
(62) Division of application No. 14/693,383, filed on Apr. 22, 2015.

(51) Int. Cl. H03H 7/18; H01P 9/00; H01P 5/18

(52) U.S. Cl. CPC H03H 7/185; H01P 5/184; H01P 9/00

(57) ABSTRACT

A variable capacitance cell includes a hybrid coupler including a first port, a second port, a third port, and a fourth port. A first variable capacitance is connected to the second port. The first variable capacitance includes one or more first variable micro-electromechanical system (MEMS) capacitor. A second variable capacitance is connected to the third port. The second variable capacitance includes one or more second variable MEMS capacitors. Control signals are applied to the first and second variable capacitances to selectively change the capacitances of the first and second variable capacitances, thereby modifying a phase difference between a signal input at the first port and a signal output from the fourth port.

### BACKGROUND

### Field of the Disclosure

The present disclosure relates generally to radiofrequency signals and, more particularly, to phase tuning of radio frequency signals.

### Description of the Related Art

Radiofrequency communication architectures typically require phase tuning of radio frequency signals. For example, the phases of signals provided to different antennas in a multiple-in-multiple-out (MIMO) antenna array may be tuned to perform beamforming of the signals transmitted or received by the MIMO antenna array. Phase tuning may also be used in other communication, automotive, or military application. For example, phase tuning may be used to perform radiofrequency power matching in power amplifiers, to implement radiofrequency oscillators, or to align radiofrequency signal paths. Conventional phase tuning is performed by manually adjusting variable capacitors based on the desired phase shift. However, the phase shift produced by the variable capacitors is fixed once the manual adjustment has been performed. Conventional phase tuning may also be performed using a mechanical filter to change the phase of the radiofrequency signal. However, mechanical filters are costly and cumbersome and consequently cannot be easily integrated with other circuits. Furthermore, many conventional phase tuning devices are restricted to tuning the phase of relatively low power radiofrequency signals, such as radiofrequency signals with a power less than 100 mW or 20 dBm.

### SUMMARY OF EMBODIMENTS

The following presents a summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

In some embodiments, an apparatus is provided for high-power phase shifting. The apparatus includes a hybrid coupler including a first port, a second port, a third port, and a fourth port. A first variable capacitance is connected to the second port. The first variable capacitance includes one or more first variable micro-electromechanical system (MEMS) capacitors. A second variable capacitance is connected to the third port. The second variable capacitance includes one or more second variable MEMS capacitors.

In some embodiments an apparatus is provided for high-power phase shifting. The apparatus includes a plurality of variable capacitance cells coupled in series. Each variable capacitance cell includes a hybrid coupler including at least a first port, a second port, a third port, and a fourth port. Each variable capacitance cell also includes a first variable capacitance connected to the second port. The first variable capacitance includes one or more first variable micro-electromechanical system (MEMS) capacitors. Each variable capacitance cell further includes a second variable capacitance connected to the third port. The second variable capacitance includes one or more second variable MEMS capacitors.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an elementary variable capacitance cell according to some embodiments.

FIG. 2 is a plot of a phase shift of an input wave after being transmitted through an elementary variable capacitance cell according to some embodiments.

FIG. 3 is a block diagram of an elementary variable capacitance cell according to some embodiments.

FIG. 4 is a diagram of a 3×3 hybrid coupler implemented using coaxial technology according to some embodiments.

FIG. 5 is a diagram of a 3×3 hybrid coupler implemented using microstrip technology according to some embodiments.

FIG. 6 is a block diagram of a 3 dB combiner according to some embodiments.

FIG. 7 is a block diagram of a 5 dB combiner according to some embodiments.

FIG. 8 is a diagram of a combiner that combines the return losses of three variable capacitances according to some embodiments.

FIG. 9 is a diagram of a delay element that is used to introduce a phase offset in a variable capacitance cell according to some embodiments.

FIG. 10 is a diagram of a switchable delay element that is used to introduce a variable phase offset in a variable capacitance cell according to some embodiments.

FIG. 11 is a block diagram of a variable capacitance cell that includes combiners as variable capacitances according to some embodiments.

FIG. 12 is a block diagram of a variable capacitance cell that includes daisy-chained combiners as variable capacitances according to some embodiments.

FIG. 13 is a block diagram of a variable capacitance cell that includes combiners that combine the return losses of three variable capacitances according to some embodiments.

FIG. 14 is a block diagram of a variable capacitance cell that includes three combiners to provide variable capacitances according to some embodiments.

FIG. 15 is a block diagram of a variable capacitance cell that includes a plurality of elementary variable capacitance cells coupled in series according to some embodiments.

### DETAILED DESCRIPTION

A high-power phase shifter can be formed of an elementary cell that includes a coupler that couples two or more nodes to two or more variable micro-electromechanical system (MEMS) capacitors so that a phase difference between a phase of a signal input at one of the nodes and a phase of a signal output at another node is determined by capacitances of the variable MEMS capacitors. For example, the coupler may be a 2×2 coupler that couples an input node and an output node to two variable MEMS capacitors to produce a phase shift between the input node and the output node. For another example, the coupler may be a 3×3 coupler that couples an input node, an output node, and a selected impedance to three variable MEMS capacitors. Some embodiments of the variable MEMS capacitors are implemented as parallel plates that are separated by a distance that is controlled by a control signal. Two or more control signals may therefore be applied to the elementary cell to vary the capacitances of the variable MEMS capacitors. Delay lines may be selectively incorporated into the elementary cell to introduce a phase offset in the phase of the signal asserted at the input node of the elementary cell. Some embodiments of the elementary cell may be coupled in series with one or more return-loss combiners that couple and input node to two or more variable MEMS capacitors.

The high power handling (HPH) limit of the phase shifter is determined by the number of variable MEMS capacitors used in the phase shifter. Increasing the number of variable MEMS capacitor increases the HPH of the phase shifter. For example, if the HPH limit of each variable MEMS capacitor is 5 watts, the HPH limit of an elementary cell that includes two variable MEMS capacitors is 10 watts and the HPH limit of an elementary cell that includes three variable MEMS capacitors is 15 watts. Consequently, coupling the elementary cell in series with one or more return-loss combiners increases the HPH limit of the phase shifter that includes the elementary cell and the return-loss combiners.

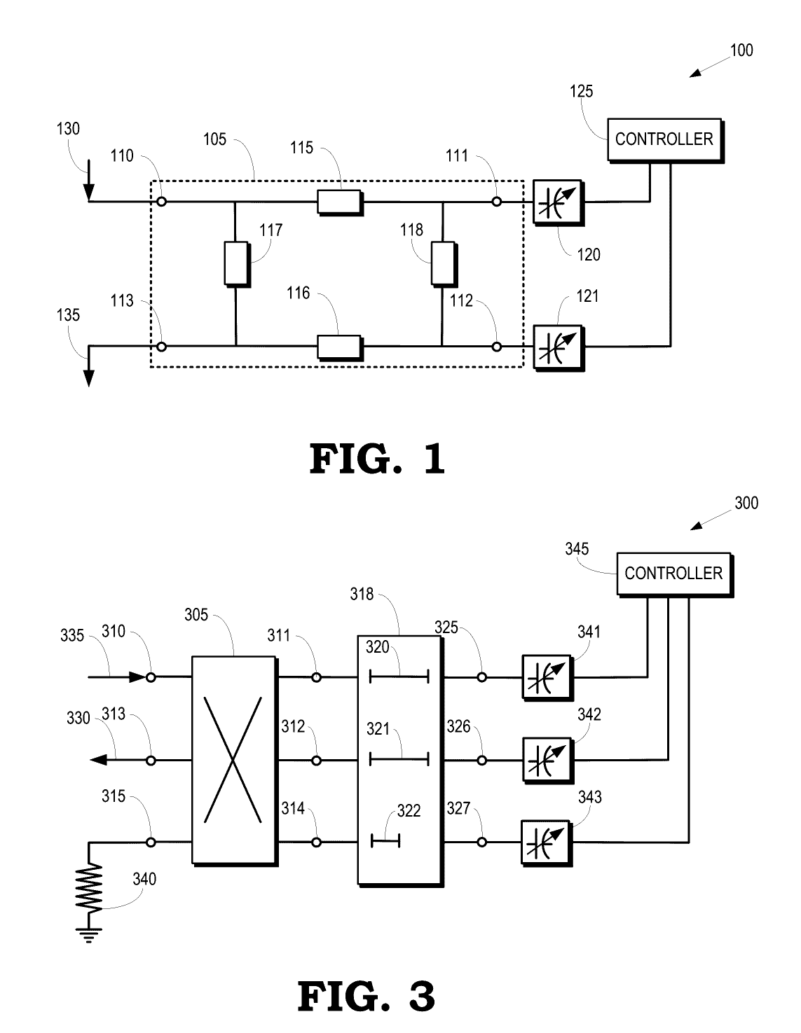

FIG. 1 is a block diagram of an elementary variable capacitance cell 100 according to some embodiments. The elementary variable capacitance cell 100 includes a hybrid coupler 105 implemented in microstrip technology that includes nodes 110, 111, 112, 113, which are referred to collectively as “the nodes 110-113.” Some embodiments of the hybrid coupler 105 are a 2×2 hybrid coupler formed of interconnected radiofrequency (RF) lines 115, 116, 117, 118, which are referred to collectively as “the RF lines 115-118.” The RF series lines 115, 116 are coupled between the nodes 110 and 111 and the RF parallel lines 117, 118 are coupled between the nodes 110 and 113. The RF lines 115-118 may be selected so that the elementary variable capacitance cell 100 has a predetermined impedance. For example, the characteristic impedances of the RF series lines 115, 116 may be selected to be 35 ohms and the characteristic impedances of the RF parallel lines 117, 118 may be selected to be 50 ohms to provide a 50 ohm impedance to the elementary variable capacitance cell 100.

The 2×2 hybrid coupler 105 may be represented by a scattering matrix:

$$S = \frac{1}{\sqrt{2}} ( \begin{matrix}0 & - i & 0 & - 1 \\ - i & 0 & - 1 & 0 \\ 0 & - 1 & 0 & - i \\ - 1 & 0 & - i & 0\end{matrix} ) \qquad ( 1 )$$

where i=\sqrt{−1} and where the port 1 is the node 110, port 2 is the node 111, port 3 is the node 113, and port 4 is the node 112. Some embodiments of the hybrid coupler 105 may have a loss of approximately −0.2 dB and the losses are substantially independent of frequency. Frequency changes caused by the hybrid coupler 105 are also low. For example, the angle error ratio for the hybrid coupler 105 corresponds to the ratio bandwidth frequency center, which may be on the order of 4%. The frequency changes are substantially independent of frequency. Furthermore, the losses and frequency changes are substantially independent of the phase shift introduced by the elementary variable capacitance cell 100, which allows the phase shift to be tuned over a relatively large range. In some embodiments, the 2×2 hybrid coupler 105 may be implemented using microstrip lines, coaxial lines, striplines, application-specific integrated circuits (ASICs), baluns, transformers, and the like. For example, the hybrid coupler 105 may be implemented as a stripline coupler, a microstrip coupler, a cross-guide coupler, a related short slot coupler, and the like.

Variable capacitances 120, 121 are coupled to the nodes 111, 112, respectively. Each of the variable capacitances 120, 121 includes at least one variable micro-electromechanical system (MEMS) capacitor that can vary its capacitance in response to control signals. For example, the variable capacitances 120, 121 may each be formed of a single MEMS capacitor and each MEMS capacitor may be formed of two parallel plates. The capacitance of the MEMS capacitors can be adjusted by modifying the distance between the parallel plates. The variable capacitances 120, 121 may also be formed of arrays of capacitors and MEMS structures such as micro switches or piezoelectric actuators that selectively couple portions of the capacitor arrays to form the variable capacitances 120, 121. The states of the micro switches or piezoelectric actuators may determine which of the MEMS structures are shorted to ground to form the variable capacitances 120, 121. In some embodiments, the variable capacitances 120, 121 each include multiple variable MEMS capacitors. For example, the variable capacitances 120, 121 may include one or more combiner circuits formed of multiple variable MEMS capacitors, as discussed herein. Some embodiments of the elementary variable capacitance cell 100 include a controller 125 that provides control signals to set or modify the capacitances of the variable capacitances 120, 121.

The elementary variable capacitance cell 100 introduces a phase difference between a signal 130 that is input at the node 110 and a signal 135 that is output at the node 113. For example, if each of the variable capacitances 120, 121 includes a variable MEMS capacitor having a capacitance of C. The variable capacitance ξis:

$$ξ = \frac{1}{iC ω}$$

where the angular frequency of the input signal 130 is ω. The normalized impedance is:

$$Z = \frac{ξ}{{Z}_{0}}$$

where Z₀ is the characteristic impedance. Thus, the return loss of the variable capacitances is Γ, where:

$$Γ = \frac{ξ - {Z}_{0}}{ξ + {Z}_{0}}$$

$$Γ = \frac{Z - 1}{Z + 1} = \frac{1 - iC ω {Z}_{0}}{1 + iC ω {Z}_{0}}$$

In FIG. 1, signals propagating from left to right at the ports 110, 113, 111, 112 may be referred to as input waves (a1, a2, a3, a4), respectively, and signals propagating from right to left at the ports 110, 113, 111, 112 may be referred to as output waves (b1, b2, b3, b4), respectively. The phase differences between the input waves (a1, a2, a3, a4) and the output waves (b1, b2, b3, b4) at the corresponding ports 110, 113, 111, 112 are functions of the capacitive load of the variable capacitances 120, 121. For example, the phase difference between the input wave al (corresponding to the signal 130) and the output wave b2 (corresponding to the signal 135) is given by b2=−j·ρ·a1, where the magnitude of ρ is 1 and the phase of ρ is:

$$ϕ = {tan}^{- 1} ( \frac{2 {XZ}_{0}}{{X}^{2} - {Z}_{0}^{2}} )$$

Examples of the capacitive loads X include MEMS capacitors and inductors that are selectively coupled into the circuit by corresponding MEMS switches. The capacitive load (or reactance) X for a MEMS capacitor is given by:

$$X = \frac{1}{C ω}$$

and the capacitive load X (or reactance) for an impedance formed by inductors (L) and a MEMS switch is given by:

X=Lω

However, other capacitive loads X may also be used in some embodiments.

The power capacity of the elementary variable capacitance cell 100 is proportional to the number of variable MEMS capacitors in the variable capacitances 120, 121. For example, the high radiofrequency power handling capacity (HPH) of each variable MEMS capacitor may be 5 watts. If each of the variable capacitances 120, 121 include a single variable MEMS capacitor, the corresponding power capacity of the elementary variable capacitance cell 100 is 2×5=10 watts.

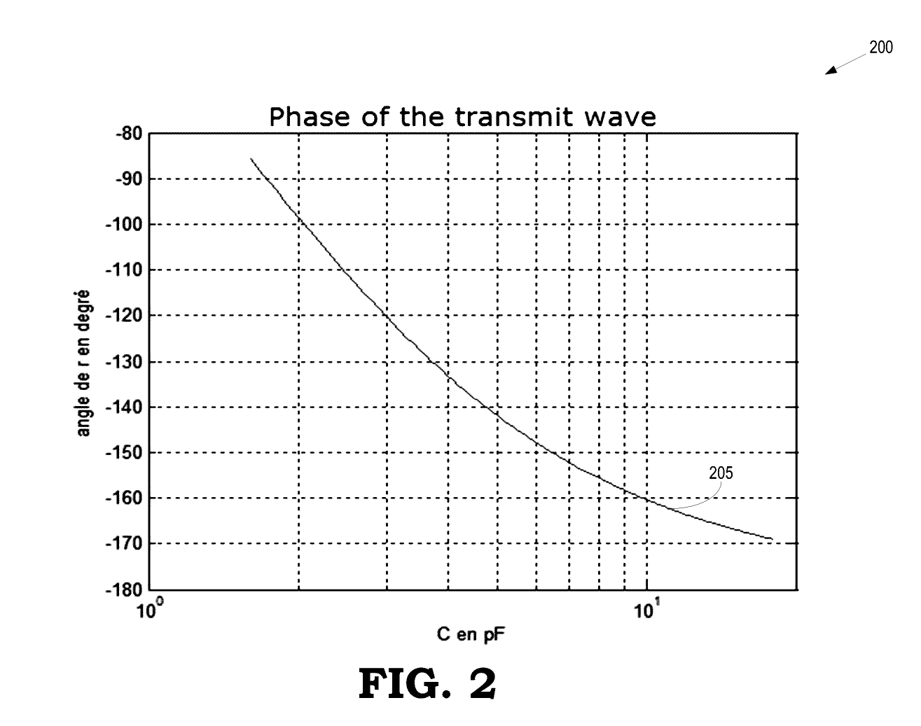

FIG. 2 is a plot 200 of a phase shift 205 of an input wave after being transmitted through an elementary variable capacitance cell according to some embodiments. The vertical axis indicates the phase shift in degrees and the horizontal axis indicates the capacitance of the variable MEMS capacitors in picofarads (pF). The variable capacitance cell includes two variable MEMS capacitors. For example, the variable capacitance cell used to produce the plot 200 may correspond to the elementary variable capacitance cell 100 shown in FIG. 1 with a single variable MEMS capacitor implemented in each of the variable capacitances 120, 121. The phase shift introduced by the variable capacitance cell ranges from −90° to almost 170° as the capacitance of the variable MEMS capacitors ranges from less than 1 pF to more than 10 pF.

FIG. 3 is a block diagram of an elementary variable capacitance cell 300 according to some embodiments. The elementary variable capacitance cell 300 includes a 3×3 hybrid coupler 305 that includes nodes 310, 311, 312, 313, 314, 315, which are referred to collectively as “the nodes 310-315.” The scattering matrix (S) of the 3×3 hybrid coupler 305 may be represented as:

$$S = \frac{1}{\sqrt{3}} ( \begin{matrix}0 & M \\ M & 0\end{matrix} )$$

$$where$$

$$M = {e}^{- jH}$$

$$H = - π ( \begin{matrix}1 / 3 & 1 & 1 \\ 1 & 1 / 3 & 1 \\ 1 & 1 & 1 / 3\end{matrix} )$$

$$and$$

$$0 ∈ {\prod }_{3 , 3}$$

$$M ∈ {\prod }_{3 , 3}$$

$$S ∈ {\prod }_{6 , 6}$$

In some embodiments, the 3×3 hybrid coupler 305 may be implemented using microstrip lines, coaxial lines, striplines, ASICs, baluns, transformers, and the like.

The nodes 311, 312, 314 of the hybrid coupler 305 are connected to a delay line network 318 that includes delay lines 320, 321, 322, which are referred to collectively as “the delay lines 320-322.” The delay lines 320-322 are coupled in series between corresponding nodes 311, 312, 314 and nodes 325, 326, 327, which are referred to collectively as “the nodes 325-327.” The delay lines 320-322 introduce corresponding phase shifts that are selected to ensure addition of the signals that produce an output signal 330 at the node 313 in response to an input signal 335 at the node 310. For example, the delay line 320 may have a length that introduces a phase shift of

$${e}^{- \frac{2 π}{3} i} ,$$

the delay line 321 may have a length that introduces a phase shift of

$${e}^{- \frac{2 π}{3} i} ,$$

and the delay line 322 may have a length that introduces a phase shift of

$${e}^{- \frac{π}{3} i} .$$

The node 315 of the hybrid coupler 305 is coupled to a predetermined load 340, such as a predetermined load of 50 ohms, and the predetermined load 340 is coupled to ground.

Variable capacitances 341, 342, 343 (collectively referred to as “the variable capacitances 341-343”) are coupled to the nodes 325-327, respectively. Each of the variable capacitances 341-343 includes at least one variable MEMS capacitor that can vary its capacitance in response to control signals. For example, the variable capacitances 341-343 may each be formed of a single MEMS capacitor and each MEMS capacitor may be formed of two parallel plates. The capacitance of the MEMS capacitors can be adjusted by modifying the distance between the parallel plates. In some embodiments, the variable capacitances 341-343 each include multiple variable MEMS capacitors. For example, the variable capacitances 341-343 may include one or more combiner circuits formed of multiple variable MEMS capacitors, as discussed herein. Some embodiments of the elementary variable capacitance cell 300 include a controller 345 that provides control signals that are used to set or modify the capacitances of the variable capacitances 341-343.

The elementary variable capacitance cell 300 introduces a phase difference between the input signal 335 and the output signal 330, as discussed above. Thus, if a unitary wave is provided as the signal 335 to the port 310, then the output wave in the signal 330 is Γe−ⁱ2π/3 thereby creating a phase shift between the input signal 335 and the output signal 330. The settable phase range of the elementary variable capacitance cell 300 is substantially the same as the phase range of the elementary variable capacitance cell 100 shown in FIG. 1, e.g., the phase range illustrated in FIG. 2. Losses in the elementary variable capacitance cell 300 may be approximately −0.3 dB. The power capacity of the elementary variable capacitance cell 300 is proportional to the number of variable MEMS capacitors in the variable capacitances 341-343. For example, the HPH of each variable MEMS capacitor may be 5 watts. If each variable capacitance 341-343 includes a single variable MEMS capacitor, the corresponding power capacity of the elementary variable capacitance cell 300 is 3×5=15 watts.

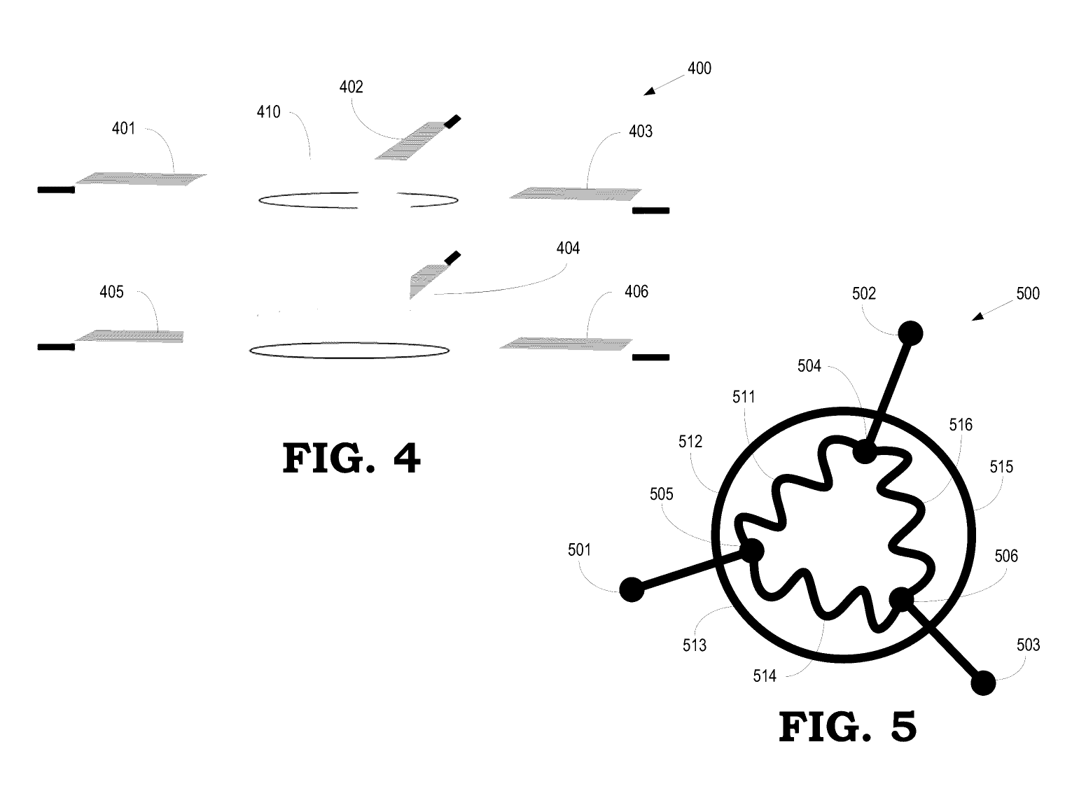

FIG. 4 is a diagram of a 3×3 hybrid coupler 400 implemented using coaxial technology according to some embodiments. The coaxial hybrid coupler 400 includes six ports 401, 402, 403, 404, 405, 406, which are collectively referred to herein as “the ports 401-406.” The ports 401-406 are interconnected by a body 410 of the hybrid coupler 400. The body 410 consists of two rings of conductive material connected in a coaxial configuration by three conductive elements. The hybrid coupler 400 may be used to implement some embodiments of the hybrid coupler 305 shown in FIG. 3. For example, the port 401 may correspond to the port 310, the port 402 may correspond to the port 313, the port 403 may correspond to the port 315, the port 404 may correspond to the port 311, the port 405 may correspond to the port 312, and the port 406 may correspond to the port 314 shown in FIG. 3.

FIG. 5 is a diagram of a 3×3 hybrid coupler 500 implemented using microstrip technology according to some embodiments. The coaxial hybrid coupler 500 includes six ports 501, 502, 503, 504, 505, 506, which are collectively referred to herein as “the ports 501-506.” The ports 501-506 are interconnected by conductive strips 511, 512, 513, 514, 515, 516. The hybrid coupler 500 may be used to implement some embodiments of the hybrid coupler 305 shown in FIG. 3. For example, the port 501 may correspond to the port 310, the port 502 may correspond to the port 313, the port 503 may correspond to the port 315, the port 504 may correspond to the port 311, the port 505 may correspond to the port 312, and the port 506 may correspond to the port 314 shown in FIG. 3.

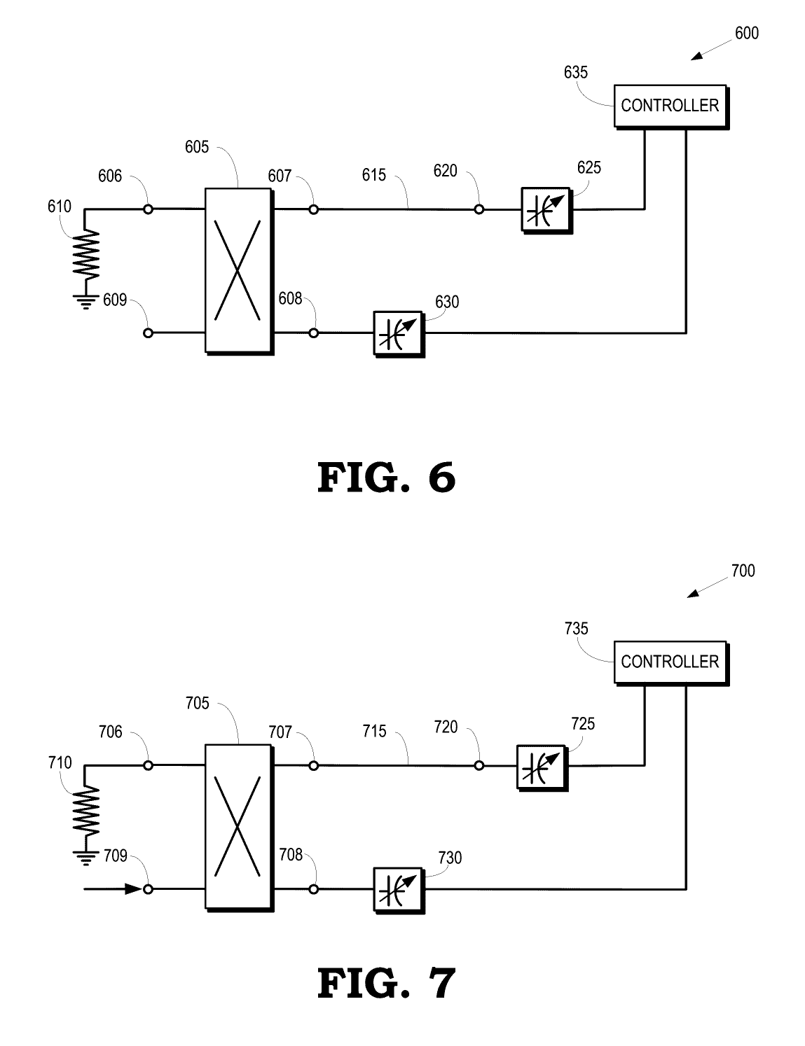

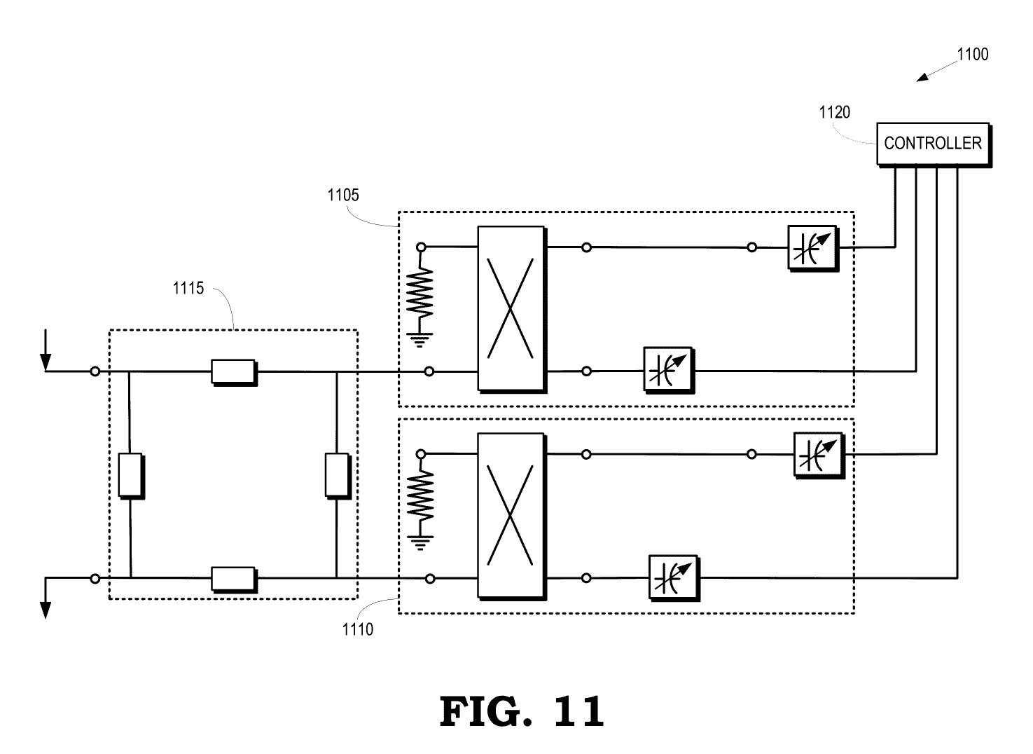

FIG. 6 is a block diagram of a 3 dB combiner 600 according to some embodiments. The combiner 600 provides an effective variable capacitance that is determined by variable capacitances in the combiner 600 Thus, in some embodiments, the variable capacitances 120, 121 shown in FIG. 2 or the variable capacitances 341-343 shown in FIG. 3 may be replaced with the combiner 600. For example, the variable capacitance cell illustrated in FIG. 11 below may be formed by replacing the variable capacitances 120, 121 shown in FIG. 2 with combiners 600. The combiner 600 includes a 3 dB hybrid coupler 605 as defined by the matrix in equation (1) that has a first port 606, a second port 607, a third port 608, and a fourth port 609. The port 606 is connected to a predetermined load 610 such as a 50 ohm load. The port 607 is coupled to a delay line 615 that terminates at a node 620. For example, the delay line 615 may have a length that corresponds to a phase of −i to ensure addition of the return waves at the port 609. However, this is only one example and other embodiments of the 3 dB combiner 600 may be implemented using other delay lines in other locations in the 3 dB combiner 600.

Variable capacitances 625, 630 are coupled to the node 620 and the port 608, respectively. Each of the variable capacitances 625, 630 includes at least one variable MEMS capacitor that can vary its capacitance in response to input signals, as discussed herein. In some embodiments, the variable capacitances 625, 630 each include multiple variable MEMS capacitors. For example, the variable capacitances 625, 630 may include one or more combiner circuits formed of multiple variable MEMS capacitors, as discussed herein. Some embodiments of the combiner 600 include a controller 635 that provides control signals that are used to set or modify the capacitances of the variable capacitances 625, 630.

Return losses at the ports 607, 608, 609 are determined by the capacitances of the variable capacitances 625, 630. For example, as discussed above, if each of the variable capacitances 625, 630 includes a single variable MEMS capacitor having a capacitance of C, the return loss at the port 607 is −Γ, the return loss at the port 608 is Γ, and the return loss at the port 609 is −Γ, where:

$$Γ = \frac{Z - 1}{Z + 1} = \frac{1 - iC ω {Z}_{0}}{1 + iC ω {Z}_{0}}$$

The angular frequency of the input signal is ω and Z₀ is the characteristic impedance of the combiner 600. Equal powers are transmitted to the variable capacitances 625, 630 via the ports 607, 608 in response to an input signal at the port 609. The power capacity of the combiner 600 is proportional to the number of variable MEMS capacitors in the variable capacitances 625, 630. For example, the HPH of each variable MEMS capacitor may be 5 watts. If each variable capacitance 625, 630 includes a single variable MEMS capacitor, the corresponding power capacity of the combiner 600 is 2×5=10 watts.

FIG. 7 is a block diagram of a 5 dB combiner 700 according to some embodiments. The scattering matrix of the 5 dB combiner 700 may be written as:

$$S = \frac{1}{\sqrt{3}} ( \begin{matrix}0 & - i & 0 & - \sqrt{2} \\ - i & 0 & - \sqrt{2} & 0 \\ 0 & - \sqrt{2} & 0 & - i \\ - \sqrt{2} & 0 & - i & 0\end{matrix} )$$

where i=\sqrt{−1} and where the port 1 is the node 706, port 2 is the node 707, port 3 is the node 709, and port 4 is the node 708. The combiner 700 may be implemented as some embodiments of the variable capacitances 120, 121 shown in FIG. 2, the variable capacitances 341-343 shown in FIG. 3, or other variable capacitances. The combiner 700 includes a 5 dB hybrid coupler 705 that has a first port 706, a second port 707, a third port 708, and a fourth port 709. The port 706 is connected to a predetermined load 710 such as a 50 ohm load. The port 707 is coupled to a delay line 715 that terminates at a node 720. For example, the delay line 715 may have a length that corresponds to a phase of −i to ensure addition of the return waves at the port 709. However, this is only one example and other embodiments of the 5 dB combiner 700 may be implemented using other delay lines in other locations in the 5 dB combiner 700.

Variable capacitances 725, 730 are coupled to the node 720 and the port 708, respectively. Each of the variable capacitances 725, 730 includes at least one variable MEMS capacitor that can vary its capacitance in response to control signals, as discussed herein. In some embodiments, the variable capacitances 725, 730 each include multiple variable MEMS capacitors. For example, the variable capacitances 725, 730 may include one or more combiner circuits formed of multiple variable MEMS capacitors, as discussed herein. Some embodiments of the combiner 700 include a controller 735 that provides control signals that are used to set or modify the capacitances of the variable capacitances 725, 730.

Return losses at the ports 707, 708, 709 determined by the capacitances of the variable capacitances 725, 730. For example, if each of the variable capacitances 725, 730 includes a single variable MEMS capacitor having a capacitance of C, the return loss at the port 707 is −Γ, the return loss at the port 708 is Γ, and the return loss at the port 709 is −Γ, as discussed above.

The 5 dB hybrid coupler 705 differs from the 3 dB hybrid coupler 605 shown in FIG. 7 because unequal powers are transmitted to the variable capacitances 725, 730 via the nodes 707, 708 in response to an input signal at the node 709. For example, the power transmitted to the variable capacitance 725 may be twice as large as the power transmitted to the variable capacitance 730. This property may be used to implement additional combiners as the variable capacitance 725, as discussed herein. The power capacity of the combiner 700 is proportional to the number of variable MEMS capacitors in the variable capacitances 725, 730. For example, the HPH of each variable MEMS capacitor may be 5 watts. If each variable capacitance 725, 730 includes a single variable MEMS capacitor, the corresponding power capacity of the combiner 700 is 2×5=10 watts.

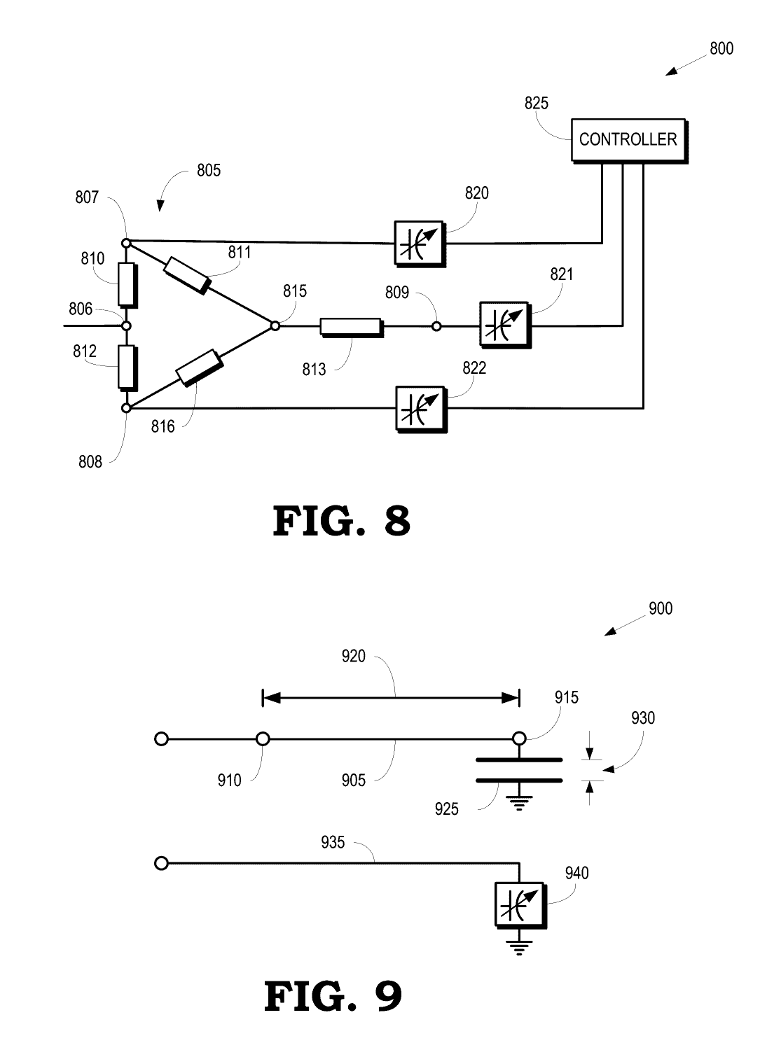

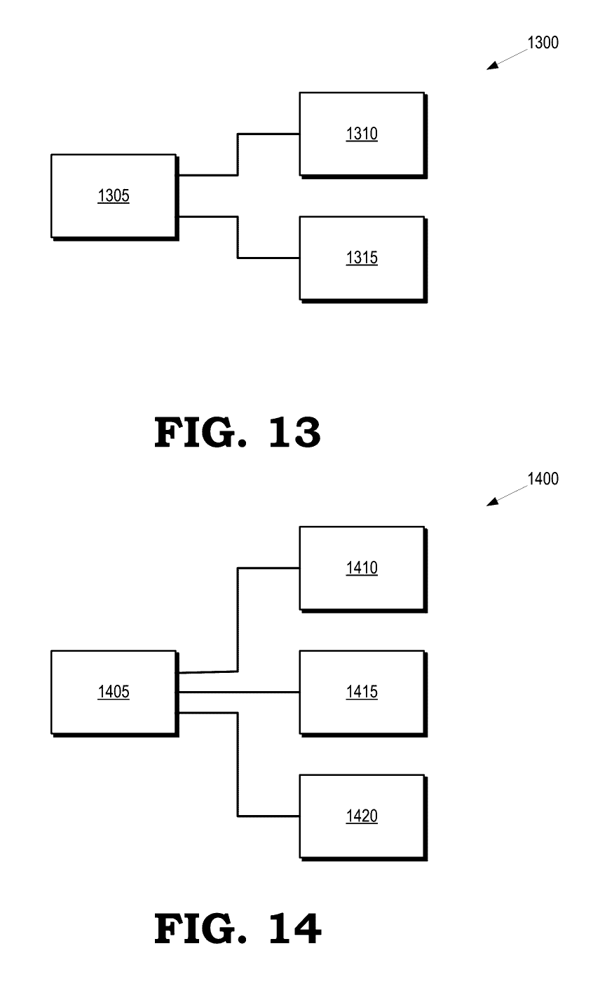

FIG. 8 is a diagram of a combiner 800 that combines the return losses of three variable capacitances according to some embodiments. The combiner 800 provides an effective variable capacitance that is determined by variable capacitances in the combiner 800. Thus, in some embodiments, the variable capacitances 120, 121 shown in FIG. 1 or the variable capacitances 341-343 shown in FIG. 3 may be replaced by the combiner 800. For example, the variable capacitance cell illustrated in FIG. 13 (which is discussed infra and which may be configured in similar fashion to the variable capacitance cell of FIG. 1) below may be formed by replacing each of the variable capacitances (1310 and 1315) shown in FIG. 2 with combiners 800. The combiner 800 includes a hybrid coupler 805 that has a first port 806, a second port 807, a third port 808, and a fourth port 809. The hybrid coupler 805 is formed of a quarter wave (e.g., λ/4, where λ is the wavelength of the input signal) line 810 connecting the first port 806 to the second port 807, a half wave (e.g., λ/2) line 811 connecting the second port 807 to the node 815, a half wave line 816 connecting the node 815 to the third port 808, a quarter wave line 812 connecting the third port 808 to the first port 806, and a quarter wave line 813 connecting the node 815 to the fourth port 809. The normalized impedances of the RF lines 810, 811, 812, 816 are 2/\sqrt{3} and the normalized impedance of the RF line 813 is 1.

The scattering matrix (S) for the hybrid coupler 805 is given by:

$$S = ( \begin{matrix}0 & - \sqrt{\frac{1}{3}} & \sqrt{\frac{1}{3}} & - \sqrt{\frac{1}{3}} \\ - \sqrt{\frac{1}{3}} & \frac{2}{3} & \frac{1}{3} & - \frac{1}{3} \\ \sqrt{\frac{1}{3}} & \frac{1}{3} & \frac{2}{3} & \sqrt{\frac{1}{3}} \\ - \sqrt{\frac{1}{3}} & - \frac{1}{3} & \sqrt{\frac{1}{3}} & \frac{2}{3}\end{matrix} )$$

Variable capacitances 820, 821, 822 (collectively referred to as “the variable capacitance is 820-822”) are coupled to the port 807, 809, 808, respectively. Each of the variable capacitances 820-822 includes at least one variable MEMS capacitor that can vary its capacitance in response to input signals, as discussed herein. In some embodiments, the variable capacitances 820-822 each include multiple variable MEMS capacitors, as discussed herein. Some embodiments of the combiner 800 include a controller 825 that provides control signals to set or modify the capacitances of the variable capacitances 820-822.

The return loss at the port 806 is determined by the capacitances of the variable capacitances 820-822. For example, if each of the variable capacitances 820-822 includes a single variable MEMS capacitor having a capacitance of C, the return loss at the port 806 is Γ, as discussed above. Equal powers are transmitted to the variable capacitances 820-822 via the ports 807-809 in response to an input signal at the port 806. The power capacity of the combiner 800 is proportional to the number of variable MEMS capacitors in the variable capacitances 820-822. For example, the HPH of each variable MEMS capacitor may be 5 watts. If each variable capacitance 820-822 includes a single variable MEMS capacitor, the corresponding power capacity of the combiner 800 is 3×5=15 watts.

FIG. 9 is a diagram of a delay element 900 that is used to introduce a phase offset in a variable capacitance cell according to some embodiments. The delay element 900 includes a delay line 905 that can be coupled between node 910 and node 915. A length 920 of the delay line 905 determines the magnitude of the phase offset that can be created by the delay element 900. Increasing the length 920 increases the phase offset and decreasing the length 920 decreases the phase offset. In the illustrated embodiment, the node 915 is connected to a variable MEMS capacitor 925. A separation 930 between the plates of the variable MEMS capacitor 925 can be varied to modify the capacitance of the variable MEMS capacitor 925, e.g., in response to control signals as discussed herein. The delay elements 900 may be represented by an equivalent circuit having a single line 935 coupled to a variable shunt capacitor 940 coupled to ground as shown in FIG. 9.

Some embodiments of the delay element 900 may be incorporated into variable capacitance cells to introduce a phase offset. For example, referring temporarily back to FIG. 1, delay element 900 may be coupled between the node 111 and the variable capacitance 120 and another delay element 900 may be coupled between the node 112 and the variable capacitance 121 to introduce a phase offset in the phase shift between the input signal 130 and the output signal 135 shown in FIG. 1. For another example, three delay elements 900 may be coupled between the nodes 325, 326, 327 and the variable capacitances 341-343 to introduce additional phase offsets in the phase shift between the input signal 335 and the output signal 330 shown in FIG. 3.

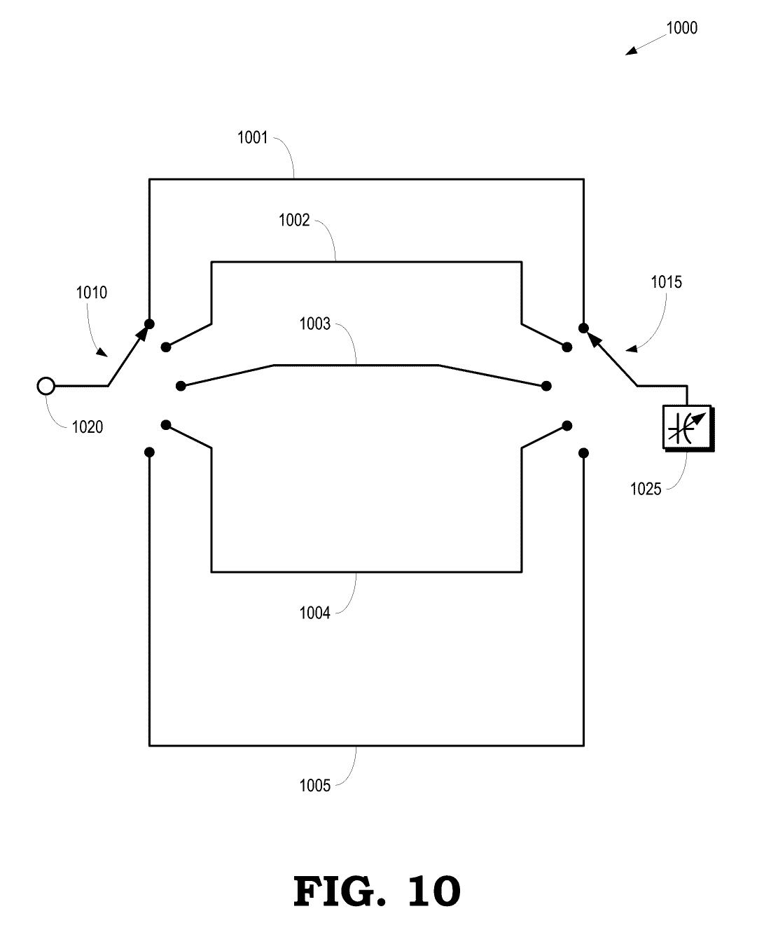

FIG. 10 is a diagram of a switchable delay element 1000 that is used to introduce a variable phase offset in a variable capacitance cell according to some embodiments. The switchable delay element 1000 includes multiple delay lines 1001, 1002, 1003, 1004, 1005 (collectively referred to as “the delay lines 1001-1005”) that have different lengths that correspond to different phase offsets. The delay lines 1001-1005 are coupled to switches 1010, 1015 that are used to selectively connect one of the delay lines 1001-1005 in series with a node 1020 and a variable capacitance 1025. Some embodiments of the delay element 1000 may be incorporated into variable capacitance cells (such as the variable capacitance cell shown in FIG. 1 or FIG. 2) to selectively introduce one of the phase offsets corresponding to one of the delay lines 1001-1005. Some embodiments of the switches 1010, 1015 may be controlled by signals provided by controllers such as the controller 125 shown in FIG. 1 or the controller 345 shown in FIG. 3

FIG. 11 is a block diagram of a variable capacitance cell 1100 that includes combiners as variable capacitances according to some embodiments. The variable capacitance cell 1100 includes an elementary variable capacitance cell 1115, which may be implemented using embodiments of the elementary variable capacitance cell 100 shown in FIG. 1. In the interest of clarity, the elements of the elementary variable capacitance cell 1115 are not indicated by reference numerals. The variable capacitances of the variable capacitance cell 1100 are provided by the combiners 1105, 1110. For example, the combiners 1105, 1110 may be implemented using embodiments of the 3 dB combiner 600 shown in FIG. 6. A controller 1120 provides control signals to the variable capacitances in the combiners 1105, 1110. Losses in the variable capacitance cell 1100 may be approximately −0.5 dB. The variable capacitance cell 1100 implements at least four variable MEMS capacitors (if each combiner 1105, 1110 includes two variable MEMS capacitors) so the power capacity is 4×HPH, which is 20 watts in the case of HPH=5 watts.

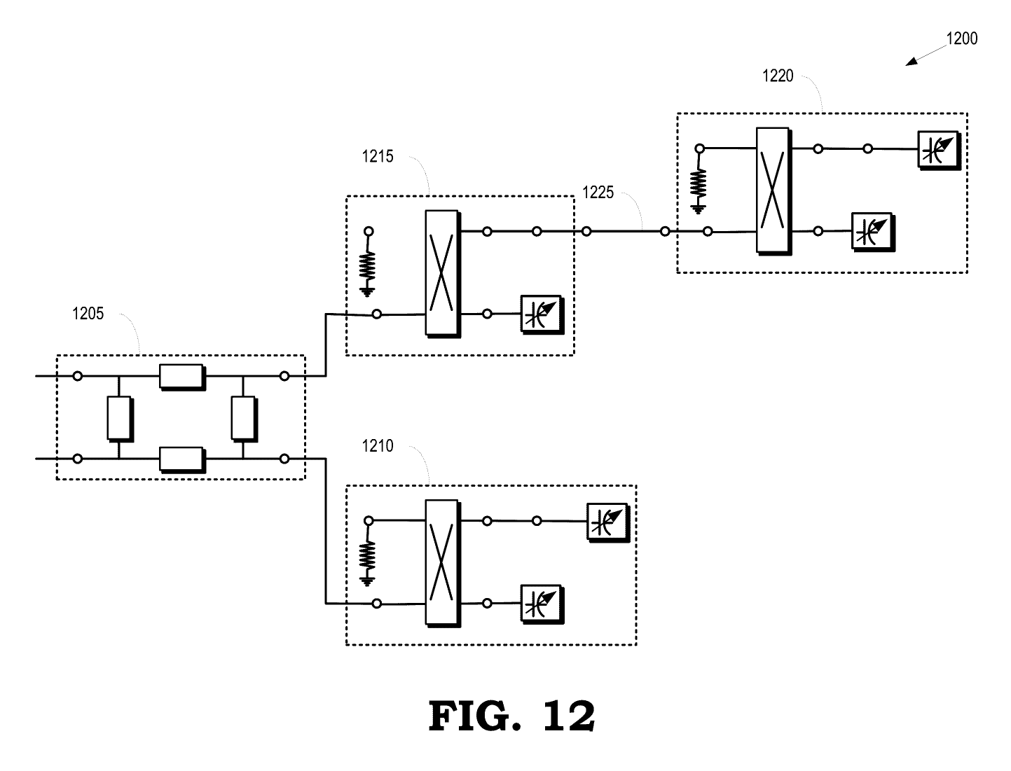

FIG. 12 is a block diagram of a variable capacitance cell 1200 that includes daisy-chained combiners as variable capacitances according to some embodiments. The variable capacitance cell 1200 includes an elementary variable capacitance cell 1205, which may be implemented using embodiments of the elementary variable capacitance cell 100 shown in FIG. 1. In the interest of clarity, the elements of the elementary variable capacitance cell 1205 are not indicated by reference numerals. One of the variable capacitances of the elementary variable capacitance cell 1205 is provided by a 3 dB combiner 1210, which may be implemented using embodiments of the 3 dB combiner 600 shown in FIG. 6. Another variable capacitance of the elementary variable capacitance cell 1205 is provided by a daisy-chained combination of a 5 dB combiner 1215 (such as the 5 dB combiner 700 shown in FIG. 7) and a 3 dB combiner 1220. The 5 dB combiner 1215 may be connected to the 3 dB combiner 1220 by a delay line 1225. For example, the delay line 1225 may have a length that corresponds to a delay of i. However, some embodiments of the variable capacitance cell 1200 may be formed of different elementary capacitances that are interconnected by delay lines of different lengths. In the interest of clarity, the elements of the combiners 1210, 1215, 1220 are not indicated by reference numerals.

A controller (not shown) may provide control signals to the variable MEMS capacitors in the combiners 1210, 1215, 1220. Losses in the variable capacitance cell 1200 may be approximately −0.6 dB. The variable capacitance cell 1200 implements at least five variable MEMS capacitors so the power capacity is 5×HPH, which is 25 watts in the case of HPH=5 watts.

FIG. 13 is a block diagram of a variable capacitance cell 1300 that includes combiners that combine the return losses of three variable capacitances according to some embodiments. The variable capacitance cell 1300 includes an elementary variable capacitance cell 1305, which may be implemented using embodiments of the elementary variable capacitance cell 100 shown in FIG. 1. The variable capacitances of the variable capacitance cell 1300 are provided by the combiners 1310, 1315, which may be implemented using embodiments of the combiner 800 shown in FIG. 8. A controller (not shown) provides control signals to the variable capacitances in the combiners 1310, 1315. Losses in the variable capacitance cell 1300 may be approximately −0.2 dB. The variable capacitance cell 1300 implements at least six variable MEMS capacitors (if each combiner 1310, 1315 includes three variable MEMS capacitors) so the power capacity is 6×HPH, which is 30 watts in the case of HPH=5 watts.

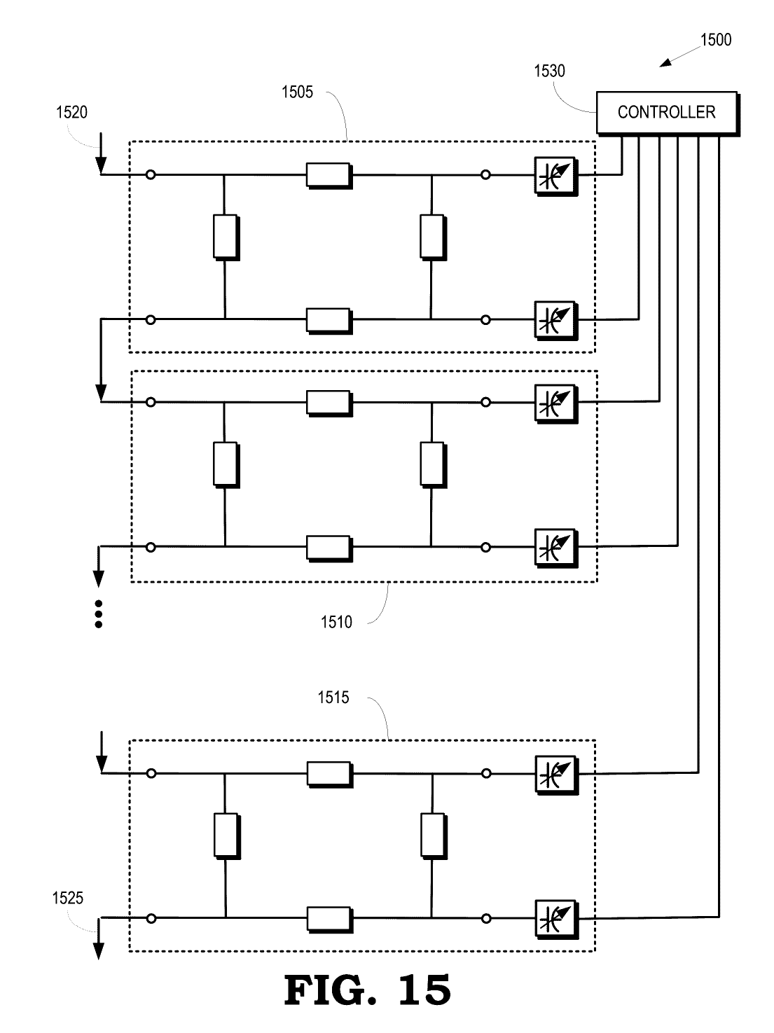

FIG. 14 is a block diagram of a variable capacitance cell 1400 that includes three combiners to provide variable capacitances according to some embodiments. The variable capacitance cell 1400 includes an elementary variable capacitance cell 1405, which may be implemented using embodiments of the elementary variable capacitance cell 300 shown in FIG. 3. The variable capacitances of the variable capacitance cell 1300 are provided by the combiners 1410, 1415, 1420, which may be implemented using embodiments of the combiner 600 shown in FIG. 6. A controller (not shown) provides control signals to the variable capacitances in the combiners 1410, 1415, 1420. Losses in the variable capacitance cell 1400 may be approximately −0.6 dB. The variable capacitance cell 1600 implements at least six variable MEMS capacitors (if each combiner 1410, 1415, 1420 includes two variable MEMS capacitors) so the power capacity is 6×HPH, which is 30 watts in the case of HPH=5 watts.

FIG. 15 is a block diagram of a variable capacitance cell 1500 that includes a plurality of elementary variable capacitance cells coupled in series according to some embodiments. The variable capacitance cell 1500 includes elementary variable capacitance cells 1505, 1510, 1515 that are coupled in series to increase the range of a variable phase shift that may be produced between an input signal 1520 and an output signal 1525. In the interest of clarity, the elements of the elementary variable capacitance cells 1505, 1510, 1515 are not indicated by reference numerals. Although three elementary variable capacitance cells 1505, 1510, 1515 are shown in FIG. 15, some embodiments of the variable capacitance cell 1500 may include more or fewer elementary variable capacitance cells coupled in series. The range of the variable phase shift that may be produced is larger when more cells are coupled in series and smaller when fewer cells are coupled in series. Some embodiments of the variable capacitance cell 1500 also include a controller 1530 for providing control signals to modify the variable capacitances in the elementary variable capacitance cells 1505, 1510, 1515.

The embodiments of variable capacitance cells described herein are intended to be illustrative and are not intended to limit the possible combinations of variable MEMS capacitors, elementary variable capacitance cells, delay lines, or combiners that may be used to construct a variable capacitance cell. Generally speaking, the variable capacitances in the elementary variable capacitance cells or combiners may be implemented using any combination of variable MEMS capacitors or combiners. Moreover, the variable MEMS capacitors and combiners may be daisy-chained to any number of levels.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. An apparatus comprising:
a hybrid coupler including at least a first port, a second port, a third port, and a fourth port;
a first variable capacitance connected to the second port, wherein the first variable capacitance comprises at least one first variable micro-electromechanical system (MEMS) capacitor;
a second variable capacitance connected to the third port, wherein the second variable capacitance comprises at least one second variable MEMS capacitor; and
at least one delay line coupled to at least one of the first port, the second port, the third port, and the fourth port, at least one of the at least one delay line including a plurality of selectable delay line segments of different lengths with individual ones of the plurality of delay lines being selectable; and
wherein a phase difference between a signal input to the first port and a signal output from the fourth port is determined by capacitances of the at least one first MEMS capacitor and the at least one second MEMS capacitor; and
wherein each of the plurality of delay line segments is configured to introduce a phase offset in the phase difference, the phase offset introduced being determined by the length of a selected one of the selectable delay line segments of the at least one delay line.

2. (canceled)

3. The apparatus of claim 1, further comprising:
a controller to provide signals to modify the capacitances of the at least one first MEMS capacitor and the at least one second MEMS capacitor.

4. The apparatus of claim 2, claim 1, wherein the at least one first MEMS capacitor has at least two plates and wherein the at least one second MEMS capacitor has at least two plates, wherein the capacitance of the at least one first MEMS capacitor is determined by
a separation between the at least two plates of the at least one first MEMS capacitor and the capacitance of the at least one second MEMS capacitor is determined by a separation between the at least two plates of the at least one second MEMS capacitor.

5. (canceled)

6. (canceled)

7. The apparatus of claim 1, wherein the first variable capacitance and the second variable capacitance comprise first and second combiners, respectively, and wherein the first and second combiners each comprise:
a coupler having a first port, a second port, a third port, and a fourth port;
a predetermined load connected to the first port;
a delay line connected to the second port;
a third variable capacitance connected to the delay line, wherein the third variable capacitance comprises at least one third variable MEMS capacitor; and
a fourth variable capacitance connected to the third port, wherein the fourth variable capacitance comprises at least one fourth variable MEMS capacitor.

8. The apparatus of claim 7, wherein the first and second combiners each comprise a 3 dB coupler and equal power is output from the coupler to the second port and the third port in response to signals provided at the fourth port.

9. The apparatus of claim 7, wherein the first and second combiners each comprise a 5 dB coupler and a first power output from the coupler to the second port in response to signals provided at the fourth port is substantially double a second power output from the coupler to the third port in response to the signals provided at the fourth port.

10. The apparatus of claim 9, wherein the third variable capacitance in the first combiner further comprises a fourth combiner, and wherein the fourth combiner comprises:
a 3 dB coupler having a first port, a second port, a third port, and a fourth port;
a predetermined load connected to the first port;
a delay line connected to the second port;
a fifth variable capacitance connected to the delay line, wherein the fifth variable capacitance comprises at least one fifth variable MEMS capacitor; and
a sixth variable capacitance connected to the third port, wherein the sixth variable capacitance comprises at least one sixth variable MEMS capacitor.

11. The apparatus of claim 1, wherein the hybrid coupler further comprises a fifth port and a sixth port, and further comprising:
a third variable capacitance connected to the fifth port, wherein the third variable capacitance comprises at least one third variable MEMS capacitor; and
a predetermined load connected to the sixth port.

12. The apparatus of claim 11, wherein:
a first delay line is coupled in series with the second port and the first variable capacitance;
a second delay line is coupled in series with the third port and the second variable capacitance; and
a third delay line is coupled in series with the fifth port and the third variable capacitance.

13. The apparatus of claim 12, wherein the first and second delay lines introduce a phase delay that is twice as large as a phase delay introduced by the third delay line.

14. The apparatus of claim 1, wherein the first variable capacitance and the second variable capacitance comprise third and fourth combiners, respectively, and wherein the third and fourth combiners each comprise:
a delay line network having a first port, a second port, a third port, and a fourth port;
a delay line connected to the fourth port;
a third variable capacitance connected to the second port, wherein the third variable capacitance comprises at least one third variable MEMS capacitor;
a fourth variable capacitance connected to the delay line, wherein the fourth variable capacitance comprises at least one fourth variable MEMS capacitor; and
a fifth variable capacitance connected to the third port, wherein the fifth variable capacitance comprises at least one fifth variable MEMS capacitor.

15. The apparatus of claim 14, wherein the delay line network comprises:
a first quarter wave delay line connecting the first port and the second port;
a second quarter wave delay line connecting the first port and the third port;
a first half wave delay line connecting the second port and the third port; and
a second half wave delay line connecting the fourth port to a midway point of the first halfway delay line.

16. An apparatus comprising:
a plurality of variable capacitance cells coupled in series, wherein each variable capacitance cell comprises:
a hybrid coupler including at least a first port, a second port, a third port, and a fourth port;
a first variable capacitance connected to the second port, wherein the first variable capacitance comprises at least one first variable micro-electromechanical system (MEMS) capacitor;
a second variable capacitance connected to the third port, wherein the second variable capacitance comprises at least one second variable MEMS capacitor; and
at least one delay line including a plurality of selectable delay line segments of different lengths coupled to at least one of the first port, the second port, the third port, and the fourth port; and
wherein a phase difference between a signal input to the first port of the hybrid coupler of each variable capacitance cell and a signal output from the fourth port of the hybrid coupler of each variable capacitance cell is determined by capacitances of the at least one first MEMS capacitor and the at least one second MEMS capacitor of each variable capacitance cell, and wherein the at least one delay line of each variable capacitance cell introduces a phase offset in the phase difference of each variable capacitance cell, the phase offset of each variable capacitance cell determined by a selected one of the selectable delay line segments of the at least one delay line of each variable capacitance cell.

17. The apparatus of claim 16, wherein a phase difference between a signal input to a first one of the plurality of variable capacitance cells and a signal output from a last one of the plurality of variable capacitance cells is equal to a sum of the phase differences of each of the plurality of variable capacitance cells.

18. The apparatus of claim 17, further comprising:
a controller to provide signals to modify the capacitances of the at least one first MEMS capacitor in each hybrid coupler and the at least one second MEMS capacitor in each hybrid coupler.

19. The apparatus of claim 17, wherein the capacitance of the at least one first MEMS capacitor in each hybrid coupler is determined by a separation between at least two plates of the at least one first MEMS capacitor and the capacitance of the at least one second MEMS capacitor in each hybrid coupler is determined by a separation between at least two plates of the at least one second MEMS capacitor.

20. The apparatus of claim 1, the apparatus further comprising a plurality of switches that selectively couple a plurality of the at least one first MEMS capacitor to ground, wherein the capacitance of the at least one first MEMS capacitor is determined by states of the plurality of switches.
